(19) United States
(12) Patent Application Publication
(10) Pub. No.: US 2026/0147063 A1
(43) Pub. Date: May 28, 2026

(54) CAPACITOR DETECTION CIRCUIT

(71) Applicant: Lite-On Technology Corporation, Taipei (TW)

(72) Inventors: Kun-Hung Lee, Taipei (TW); Yun Chieh Hsu, Taipei (TW)

(73) Assignee: Lite-On Technology Corporation, Taipei (TW)

(21) Appl. No.: 19/047,651

(22) Filed: Feb. 7, 2025

(30) Foreign Application Priority Data
Nov. 25, 2024 (CN) 202411696501.8

(51) Int. Cl. G01R 31/64; G01R 19/04; G01R 19/165

(52) U.S. Cl. CPC G01R 31/64; G01R 19/04; G01R 19/16571

(57) ABSTRACT

A capacitor detection circuit is provided. The capacitor detection circuit is located in a power supply unit and is used to detect a capacitor in the power supply unit. The capacitor detection circuit includes a bandwidth filter circuit, a buffer and peak detection circuit, and a comparator circuit. The bandwidth filter circuit receives a node voltage of the capacitor to provide a filtered voltage. The buffer and peak detection circuit receives the filtered voltage to provide a peak voltage. The comparator circuit receives the peak voltage and provides a capacitor fault signal based on a comparison result of the peak voltage and a reference voltage.

### CROSS-REFERENCE TO RELATED APPLICATION

This application claims the priority benefit of China application serial no. 202411696501.8, filed on Nov. 25, 2024. The entirety of the above-mentioned patent application is hereby incorporated by reference herein and made a part of this specification.

### BACKGROUND

### Technical Field

The disclosure relates to an electronic element detection circuit, and in particular relates to a capacitor detection circuit.

### Description of Related Art

A power supply unit is an indispensable component in electronic devices, primarily responsible for converting alternating current (AC) to stable direct current (DC) for use by various electronic devices. At present, most general power supply units are switching mode power supplies, and the input voltage automatically adapts to the domestic power parameters of the home location. However, some power supply units may necessitate the adjustment of a switch to accommodate to the domestic voltage. Semiconductor switching elements and capacitors are the elements most likely to fail in power electronic systems. Therefore, the detection of the operational state or lifespan of capacitors, in order to issue warnings prior to their complete loss of functionality, has become an important issue for stable operation of the power supply unit.

### SUMMARY

A capacitor detection circuit that may instantly detect the ripple voltage of the capacitor to determine whether the equivalent series resistance of the capacitor is too high, thereby determining whether the capacitor is abnormal, is provided in the disclosure.

The capacitor detection circuit of the disclosure is located in a power supply unit and used to detect a capacitor in the power supply unit. The capacitor detection circuit includes a bandwidth filter circuit, a buffer and peak detection circuit, and a comparator circuit. The bandwidth filter circuit receives a node voltage of the capacitor to provide a filtered voltage. The buffer and peak detection circuit receives the filtered voltage to provide a peak voltage. The comparator circuit receives the peak voltage and provides a capacitor fault signal based on a comparison result of the peak voltage and a reference voltage.

Based on the above, in the capacitor detection circuit of the embodiment of the disclosure, the capacitor detection circuit compares the peak value of the filtered voltage obtained from the node voltage of the capacitor with the reference voltage to determine whether the capacitor may be faulty. Hereby, as the capacitor detection circuit operates in an online monitoring mode, it enables detection to be conducted during the operation of the power supply unit without affecting the operation of the system.

In order to make the above-mentioned features and advantages of the disclosure comprehensible, embodiments accompanied with drawings are described in detail below.

### BRIEF DESCRIPTION OF THE DRAWINGS

FIG. 1A is a circuit schematic diagram illustrating a capacitor detection circuit according to the first embodiment of the disclosure.

FIG. 1B is a schematic diagram illustrating the driving waveform of the capacitor detection circuit according to the embodiment of the disclosure.

FIG. 2 is a circuit schematic diagram illustrating a capacitor detection circuit according to the second embodiment of the disclosure.

FIG. 3 is a circuit schematic diagram illustrating a capacitor detection circuit according to the third embodiment of the disclosure.

FIG. 4 is a system schematic diagram illustrating a power supply unit using a capacitor detection circuit of an embodiment of the disclosure.

### DETAILED DESCRIPTION OF DISCLOSED EMBODIMENTS

In power supply units, the main function of electrolytic capacitors is to smooth voltage ripples and store electrical energy. The benefit of using electrolytic capacitors is that they may provide high capacitance and have high volumetric efficiency, thereby offering exceptional cost-effectiveness. However, the disadvantages of electrolytic capacitors are that they have high equivalent series resistance (ESR) and equivalent series inductance (ESL), and have poor stability at low temperatures. The electrolytic capacitor is the element with the shortest lifespan in the power supply unit, so it is necessary to monitor the state of the electrolytic capacitor.

Although offline monitoring may provide accurate assessments, it necessitates the removal of capacitors from the power supply unit, rendering the offline method impractical for implementation. Relatively speaking, online monitoring may diagnose capacitor lifespan by monitoring specific functions. Although it requires additional detection circuitry and cannot provide precise determinations, it is relatively easy to implement. Compared with offline monitoring, which requires system shutdown for detection, online monitoring enables detection when the power supply unit is operating, resulting in minimal impact on the system.

Generally speaking, the root causes of electrolytic capacitor failure are roughly divided into excessive ambient temperature, excessive voltage stress, excessive ripple current, and continuous charge and discharge cycles (i.e., pulse discharge). Under conditions of excessive ambient temperature, the main failure mechanism is that the evaporation of the electrolyte leads to an increase in internal pressure within the capacitor. This results in capacitance loss and an increase in ESR. Consequently, the pressure relief vent may activate, and the internal pressure may become excessively high. Under conditions of excessive voltage stress, the main failure mechanisms are the degradation of the oxide layer and the reduction in capacitance of the anode metal foil, consequently leading to an increase in leakage current, capacitance loss, and an increase in ESR. Under conditions of excessive ripple current, the main failure mechanism is the evaporation of the electrolyte, resulting in capacitance loss and an increase in ESR. Under the conditions of continuous charge and discharge cycles, the main failure mechanism is the formation of an additional dielectric layer, leading to electrolyte evaporation and a reduction in the capacitance of the cathode metal foil. Subsequently, the gases generated during the oxide layer formation process result in excessive internal pressure. This pressure increase causes capacitance loss and results in the activation of the pressure relief vent.

In the event of electrolytic capacitor failure, the functions that may be affected by the power supply unit are the charging slope, ripple voltage, dynamic voltage, thermal condition, and energy efficiency. The charging slope is directly proportional to the capacitance and ESR of the electrolytic capacitor. The ripple voltage is directly proportional to the capacitance and ESR of the electrolytic capacitor. The dynamic voltage is directly proportional to the capacitance and ESR of the electrolytic capacitor. The thermal condition is directly proportional to the ESR of the electrolytic capacitor. The energy efficiency is directly proportional to the ESR of the electrolytic capacitor.

Based on the above, online monitoring may basically be carried out by monitoring the ripple voltage, dynamic voltage, and thermal condition of the electrolytic capacitor. The ripple voltage is a state that is easy to detect through circuits. Therefore, the ripple voltage detection circuit has the advantages of simple implementation and low cost. That is, the ripple voltage detection circuit is easier to implement and does not significantly increase the overall cost of the power supply unit. Therefore, the embodiment of the disclosure primarily focuses on a detection circuit for setting ripple voltage. However, other applications are not excluded, as these may be determined based on the specific application environment.

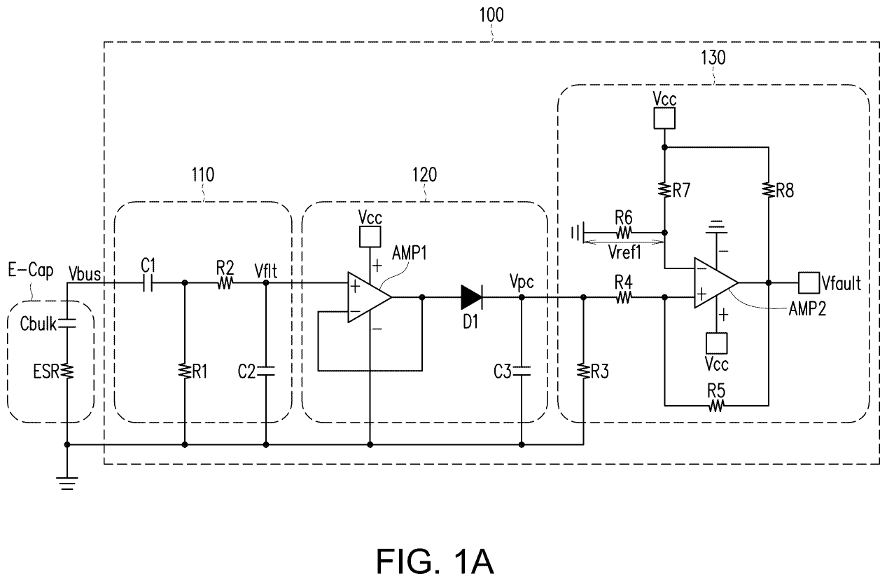

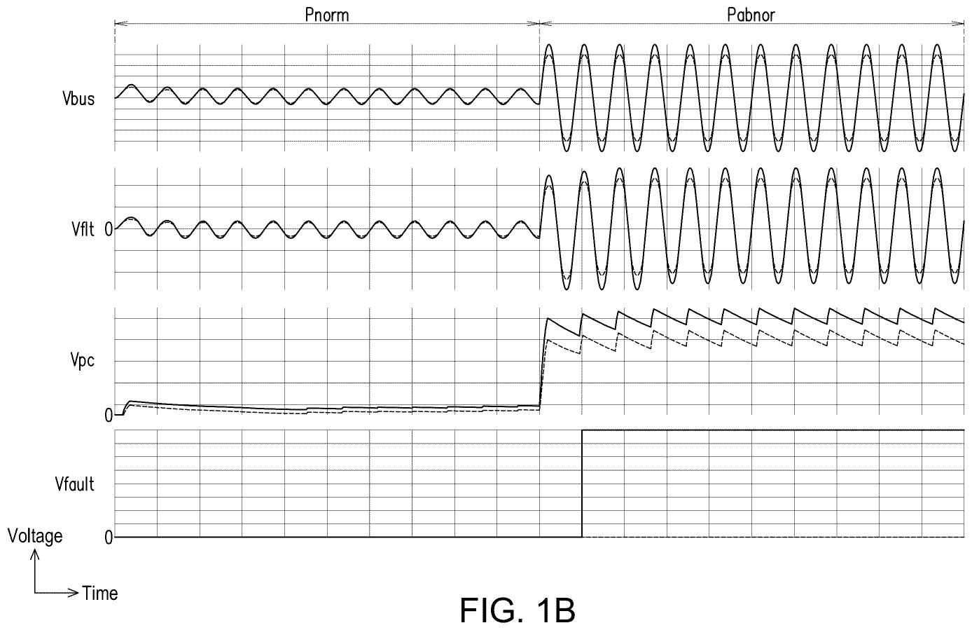

FIG. 1A is a circuit schematic diagram illustrating a capacitor detection circuit according to the first embodiment of the disclosure. Referring to FIG. 1A and FIG. 1B, in this embodiment, the capacitor detection circuit 100 detects the ESR of the electrolytic capacitor by detecting the ripple voltage across the electrolytic capacitor, and since to the relationship between the dissipation factor (DF) and the ESR is ESR·2π·f·C, the dissipation factor may be monitored indirectly, where f is the frequency of the voltage across the electrolytic capacitor (or input voltage), and C is the capacitance of the electrolytic capacitor. Furthermore, compared to an electrolytic capacitor in a normal state, the capacitance of an electrolytic capacitor in an abnormal state will decrease, the ESR will increase, and the dissipation factor will increase.

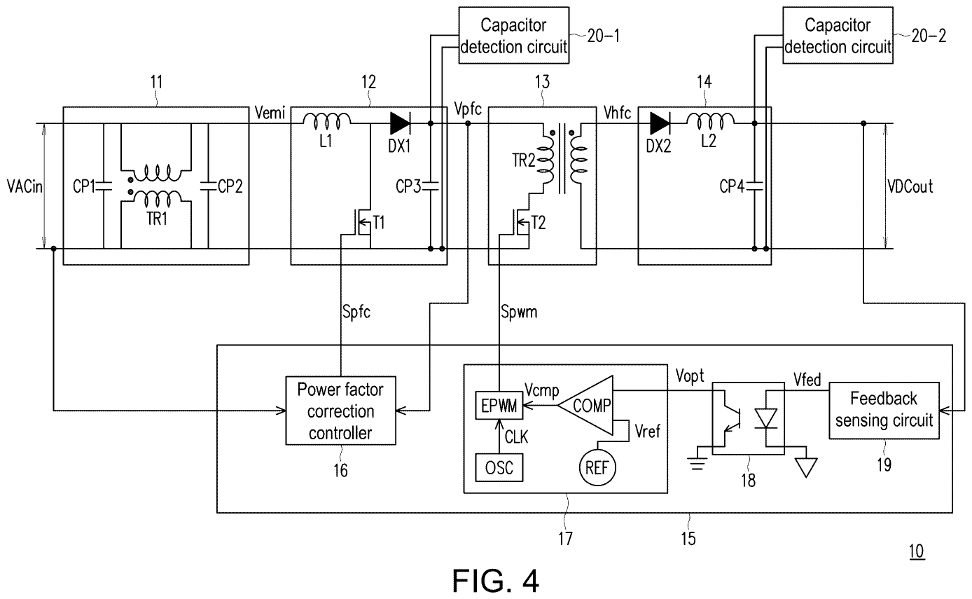

In this embodiment, the capacitor detection circuit 100 may be located in a power supply unit (e.g., the power supply unit 10 as shown in FIG. 4) to detect the capacitor (e.g., the capacitor CP3 or CP4 as shown in FIG. 4) in the power supply unit, and includes, for example, a bandwidth filter circuit 110, a buffer and peak detection circuit 120, and a comparator circuit 130.

The bandwidth filter circuit 110 receives the node voltage Vbus of the capacitor E-cap (equal to the cross-voltage of the capacitor E-cap) to provide a filtered voltage Vflt in which the DC level is filtered out and the AC signal remains. The capacitor E-cap may be regarded as consisting of the capacitor body Cbulk and ESR. The buffer and peak detection circuit 120 receives the filtered voltage Vflt, which is used to capture (or sample) the maximum positive value (i.e., the peak value) of the filtered voltage Vflt to provide the peak voltage Vpc. The comparator circuit 130 receives the peak voltage Vpc and provides a capacitor fault signal Vfault indicating whether the capacitor E-cap may be faulty based on the comparison result between the peak voltage Vpc and the reference voltage Vref1.

Based on the above, the capacitor detection circuit 100 compares the peak value of the filtered voltage Vflt obtained from the node voltage Vbus of the capacitor E-cap with the reference voltage Vref1 to determine whether the capacitor E-cap may be faulty. Hereby, as the capacitor detection circuit 100 operates in an online monitoring mode, it enables detection to be conducted during the operation of the power supply unit without affecting the operation of the system. Moreover, since the filtering, sampling, and comparison operations of the capacitor detection circuit 100 are simple behaviors, they may be implemented with a simple circuit, thereby reducing the required hardware cost.

In this embodiment, the bandwidth filter circuit 110 includes, for example, a first capacitor C1, a first resistor R1, a second resistor R2, a first capacitor C1, and a second capacitor C2. The first capacitor C1 has a first terminal receiving the node voltage Vbus, and a second terminal. The first resistor R1 is coupled between the second terminal of the first capacitor C1 and the ground voltage. The second resistor R2 has a first terminal coupled to the second terminal of the first capacitor C1, and a second terminal providing the filtered voltage Vflt. The second capacitor C2 is coupled between the second terminal of the second resistor R2 and the ground voltage.

In this embodiment, the buffer and peak detection circuit 120 includes, for example, a first differential amplifier AMP1, a first diode D1, and a third capacitor C3. The first differential amplifier AMP1 has a positive input terminal receiving the filtered voltage Vflt, a positive power terminal receiving the supply voltage Vcc, a negative input terminal, a negative power terminal receiving the ground voltage, and an output terminal coupled to the negative input terminal of the first differential amplifier AMP1. The first diode D1 has an anode coupled to the output terminal of the first differential amplifier AMP1, and a cathode providing a peak voltage Vpc. The third capacitor C3 is coupled between the cathode of the first diode D1 and the ground voltage.

In this embodiment, the comparator circuit 130 includes, for example: a second differential amplifier AMP2, a third resistor R3, a fourth resistor R4, a fifth resistor R5, a sixth resistor R6, a seventh resistor R7, and an eighth resistor R8. The second differential amplifier AMP2 has a positive input terminal, a positive power terminal receiving the supply voltage Vcc, a negative input terminal, a negative power terminal receiving the ground voltage, and an output terminal providing the capacitor fault signal Vfault.

The third resistor R3 is coupled between the peak voltage Vpc and the ground voltage. The fourth resistor R4 is coupled between the peak voltage Vpc and the positive input terminal of the second differential amplifier AMP2. The fifth resistor R5 is coupled between the positive input terminal of the second differential amplifier AMP2 and the output terminal of the second differential amplifier AMP2. The sixth resistor R6 is coupled between the ground voltage and the negative input terminal of the second differential amplifier AMP2 to form the reference voltage Vref1. The seventh resistor R7 is coupled between the supply voltage Vcc and the negative input terminal of the second differential amplifier AMP2. The eighth resistor R8 is coupled between the supply voltage Vcc and the output terminal of the second differential amplifier AMP2.

In this embodiment, the reference voltage Vref1 at the negative input terminal of the second differential amplifier AMP2 may be a fixed level. Furthermore, the comparator circuit 130 operates as a hysteresis comparator, but the embodiment of the disclosure is not limited thereto.

In this embodiment, the capacitor E-cap may be an electrolytic capacitor. Furthermore, the capacitor E-cap may be an aluminum electrolytic capacitor, but the embodiment of the disclosure is not limited thereto.

FIG. 1B is a schematic diagram illustrating the driving waveform of the capacitor detection circuit according to the embodiment of the disclosure. Referring to FIG. 1A and FIG. 1B, in this embodiment, when the capacitor E-cap is in a normal state (as shown by the normal operation period Pnorm), the ESR is lower, so the node voltage Vbus has smaller ripples. That is, the filtered voltage Vflt has a smaller amplitude. At this time, the peak voltage Vpc is at a lower level (i.e., less than the reference voltage Vref1), so that the capacitor fault signal Vfault shows a low voltage level, indicating that the capacitor E-cap is normal.

On the contrary, when the capacitor E-cap is in an abnormal state (as shown by the abnormal operation period Pabnor), the ESR is higher, so the node voltage Vbus has a larger ripple. That is, the filtered voltage Vflt has a higher amplitude. At this time, the peak voltage Vpc is at a higher level (i.e., greater than the reference voltage Vref1), so that the capacitor fault signal Vfault shows a high voltage level, indicating that the capacitor E-cap may be abnormal.

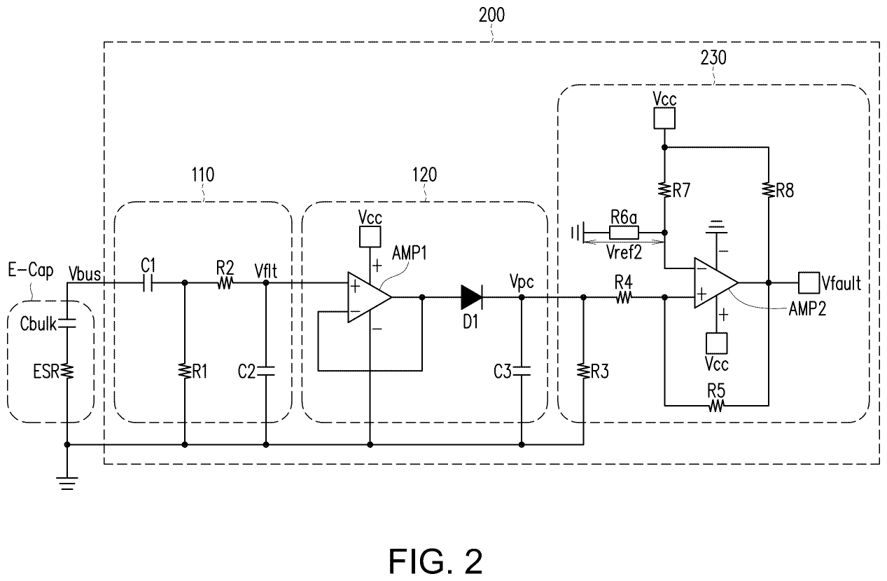

FIG. 2 is a circuit schematic diagram illustrating a capacitor detection circuit according to the second embodiment of the disclosure. Referring to FIG. 1A and FIG. 2, the capacitor detection circuit 200 is substantially the same as the capacitor detection circuit 100, where the difference lies in the comparator circuit 230 of the capacitor detection circuit 200. The same or similar reference numerals are used for the same or similar elements.

Under the condition that the capacitor E-cap is an electrolytic capacitor, the ESR of the capacitor E-cap is related to temperature, and the stability of the capacitor E-cap at low temperature is poor, so the reference voltage Vref2 of the negative input terminal of the second differential amplifier AMP2 may be changed in response to the ambient temperature to compensate for the resistance change of the ESR caused by temperature.

In the embodiment of the disclosure, the ESR of the capacitor E-cap may be inversely proportional to the temperature (i.e., the higher the temperature, the lower the ESR). At this time, the reference voltage Vref2 should decrease and change in response to the increase in ambient temperature. Based on the above, the sixth resistor R6a of the comparator circuit 230 may be designed as a thermistor with a negative temperature coefficient, and may have the same negative temperature coefficient as the ESR of the capacitor E-cap.

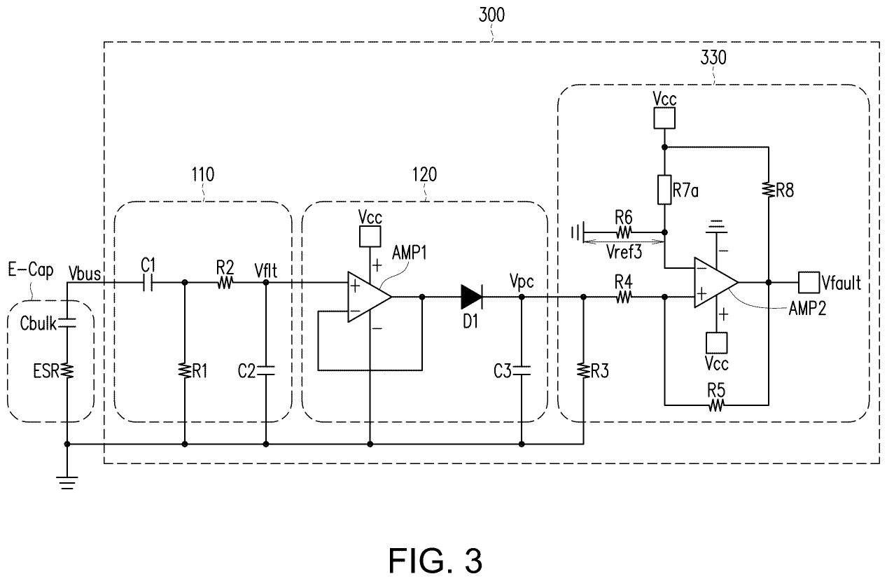

FIG. 3 is a circuit schematic diagram illustrating a capacitor detection circuit according to the third embodiment of the disclosure. Referring to FIG. 1A and FIG. 3, the capacitor detection circuit 300 is substantially the same as the capacitor detection circuit 100, where the difference lies in the comparator circuit 330 of the capacitor detection circuit 300. The same or similar reference numerals are used for the same or similar elements.

As described in the embodiment of FIG. 2 above, the ESR of the capacitor E-cap may be inversely proportional to the temperature (i.e., the higher the temperature, the lower the ESR). Therefore, the reference voltage Vref3 shown in FIG. 3 should decrease and change in response to the increase in ambient temperature. Based on the above, the seventh resistor R7a of the comparator circuit 330 may be designed as a thermistor with a positive temperature coefficient. Furthermore, it may have a temperature coefficient corresponding to the ESR of the capacitor E-cap.

FIG. 4 is a system schematic diagram illustrating a power supply unit using a capacitor detection circuit of an embodiment of the disclosure. Referring to FIG. 1A and FIG. 4, in this embodiment, the power supply unit 10 includes, for example, an electromagnetic interference (EMI) filter 11, a power factor correction (PFC) converter and filter 12, a high frequency converter 13, an output rectifier and filter 14, a control circuit 15, and capacitor detection circuits 20-1, 20-2. For the capacitor detection circuits 20-1 and 20-2, reference may be made to the embodiments shown in FIG. 1A, FIG. 2 and FIG. 3, and the circuits may be combined as required, and the embodiment of the disclosure is not limited thereto.

The electromagnetic interference filter 11 receives the AC input voltage VACin to provide the interference removal voltage Vemi, and includes, for example, capacitors CP1 and CP2 and a transformer TR1. The capacitors CP1 and CP2 are connected in parallel between the live line and the neutral line of the AC input voltage VACin, and the primary side and the secondary side of the transformer TR1 are respectively coupled to the live line and the neutral line of the AC input voltage VACin.

The power factor correction (PFC) converter and filter 12 receives the interference removal voltage Vemi to provide the power factor correction rectified voltage Vpfc, and includes, for example, an inductor L1, a diode DX1, a transistor T1, and a capacitor CP3. One side of the inductor L1 is coupled to the live line of the AC input voltage VACin. The first source/drain of the transistor T1 is coupled to the other side of the inductor L1, the second source/drain of the transistor T1 is coupled to the neutral line of the AC input voltage VACin, and the gate of the transistor T1 receives the power factor correction signal Spfc. The anode of the diode DX1 is coupled to the other side of the inductor L1, and the cathode of the diode DX1 provides the power factor correction rectified voltage Vpfc. The capacitor CP3 is coupled between the cathode of diode DX1 and the neutral line of AC input voltage VACin.

The high frequency converter 13 receives the power factor correction rectified voltage Vpfc to provide the high frequency conversion voltage Vhfc, and includes, for example, a transformer TR2 and a transistor T2. The transistor T2 has a first source/drain, a gate receiving the pulse-width modulation signal Spwm, and a second source/drain coupled to the neutral line of the AC input voltage VACin. The primary side of the transformer TR2 is coupled between the cathode of the diode DX1 (i.e., the power factor correction rectified voltage Vpfc) and the first source/drain of the transistor T2. The secondary side of the transformer TR2 provides the high frequency conversion voltage Vhfc.

The output rectifier and filter 14 receives the power factor correction rectified voltage Vpfc to provide the high frequency conversion voltage Vhfc, and includes, for example, a diode DX2, an inductor L2, and a capacitor CP4. The diode DX2, the inductor L2, and the secondary side of the transformer TR2 are connected in series with the voltage across the DC output voltage VDCout, and the capacitor CP4 is connected in parallel with the voltage across the DC output voltage VDCout.

The control circuit 15 includes, for example, a power factor correction controller 16, a pulse-width modulation (PWM) controller 17, an optical coupler 18, and a feedback sensing circuit 19. The power factor correction controller 16 is coupled to the neutral line of the AC input voltage VACin, and receives the power factor correction rectified voltage Vpfc to provide the power factor correction signal Spfc accordingly. The feedback sensing circuit 19 provides the feedback voltage Vfed based on the DC output voltage VDCout, the optical coupler 18 provides the coupling voltage Vopt based on the feedback voltage Vfed, and the pulse-width modulation controller 17 receives the coupling voltage Vopt to provide the pulse-width modulation signal Spwm.

In this embodiment, the pulse-width modulation controller 17 includes, for example, a reference power source REF, a comparator COMP, an oscillator OSC, and a pulse-width modulation circuit EPWM. The reference power source REF provides the reference voltage Vref, and the oscillator OSC provides the clock signal CLK. The comparator COMP compares the reference voltage Vref and the coupling voltage Vopt to provide a comparison result voltage Vcomp. The pulse-width modulation circuit EPWM provides a pulse-width modulation signal Spwm based on the clock signal CLK and the comparison result voltage Vcomp.

The capacitor detection circuit 20-1 is coupled to both terminals of the capacitor CP3 for detecting the state of the capacitor CP3. Furthermore, the capacitor detection circuit 20-2 is coupled to both terminals of the capacitor CP4 for detecting the state of the capacitor CP4.

In the embodiment of the disclosure, the capacitor fault signal Vfault may be used alone to indicate the state of the capacitor. Alternatively, the capacitor fault signal Vfault may be utilized in conjunction with other indicative characteristics of the capacitor to determine the state of the capacitor, such as the dynamic voltage and thermal condition of the capacitor, but the embodiment of the disclosure is not limited thereto.

To sum up, in the capacitor detection circuit of the embodiment of the disclosure, the capacitor detection circuit compares the peak value of the filtered voltage obtained from the node voltage of the capacitor with the reference voltage to determine whether the capacitor may be faulty. Hereby, as the capacitor detection circuit operates in an online monitoring mode, it enables detection to be conducted during the operation of the power supply unit without affecting the operation of the system. Moreover, since the filtering, sampling, and comparison operations of the capacitor detection circuit are simple behaviors, they may be implemented with a simple circuit, thereby reducing the required hardware cost.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. A capacitor detection circuit, located in a power supply unit and used to detect a capacitor in the power supply unit, comprising:
a bandwidth filter circuit, receiving a node voltage of the capacitor to provide a filtered voltage;
a buffer and peak detection circuit, receiving the filtered voltage to provide a peak voltage; and
a comparator circuit, receiving the peak voltage to provide a capacitor fault signal based on a comparison result of the peak voltage and a reference voltage.

2. The capacitor detection circuit according to claim 1, wherein the bandwidth filter circuit comprises:
a first capacitor, having a first terminal receiving the node voltage, and a second terminal;
a first resistor, coupled between the second terminal of the first capacitor and a ground voltage;
a second resistor, having a first terminal coupled to the second terminal of the first capacitor, and a second terminal providing the filtered voltage; and
a second capacitor, coupled between the second terminal of the second resistor and the ground voltage.

3. The capacitor detection circuit according to claim 2, wherein the buffer and peak detection circuit comprises:
a first differential amplifier, having a positive input terminal receiving the filtered voltage, a positive power terminal receiving a supply voltage, a negative input terminal, a negative power terminal receiving the ground voltage, and an output terminal coupled to the negative input terminal of the first differential amplifier;
a first diode, having an anode coupled to the output terminal of the first differential amplifier, and a cathode providing the peak voltage; and
a third capacitor, coupled between the cathode of the first diode and the ground voltage.

4. The capacitor detection circuit according to claim 3, wherein the comparator circuit operates as a hysteresis comparator.

5. The capacitor detection circuit according to claim 4, wherein the comparator circuit comprises:
a second differential amplifier, having a positive input terminal, a positive power terminal receiving the supply voltage, a negative input terminal, a negative power terminal receiving the ground voltage, and an output terminal providing the capacitor fault signal;
a third resistor, coupled between the peak voltage and the ground voltage;
a fourth resistor, coupled between the peak voltage and the positive input terminal of the second differential amplifier;
a fifth resistor, coupled between the positive input terminal of the second differential amplifier and the output terminal of the second differential amplifier;
a sixth resistor, coupled between the ground voltage and the negative input terminal of the second differential amplifier to form the reference voltage;
a seventh resistor, coupled between the supply voltage and the negative input terminal of the second differential amplifier; and
an eighth resistor, coupled between the supply voltage and the output terminal of the second differential amplifier.

6. The capacitor detection circuit according to claim 5, wherein the reference voltage at the negative input terminal of the second differential amplifier is a fixed level.

7. The capacitor detection circuit according to claim 5, wherein the reference voltage of the negative input terminal of the second differential amplifier changes in response to an ambient temperature.

8. The capacitor detection circuit according to claim 7, wherein the reference voltage decreases and changes in response to an increase in the ambient temperature.

9. The capacitor detection circuit according to claim 8, wherein the sixth resistor is a thermistor with a negative temperature coefficient.

10. The capacitor detection circuit according to claim 8, wherein the seventh resistor is a thermistor with a positive temperature coefficient.

11. The capacitor detection circuit according to claim 1, wherein the capacitor is an electrolytic capacitor.

12. The capacitor detection circuit according to claim 1, wherein the capacitor is an aluminum electrolytic capacitor.
